(19) United States
(12) Patent Application Publication
(10) Pub. No.: US 2017/0212046 A1
(43) Pub. Date: Jul. 27, 2017

(54) MEASUREMENT PARAMETERS FOR QC METROLOGY OF SYNTHETICALLY GENERATED DIAMOND WITH NV CENTERS

(71) Applicant: Lockheed Martin Corporation, Bethesda, MD (US)

(72) Inventor: Jeff D. Cammerata, Medford Lakes, NJ (US)

(73) Assignee: Lockheed Martin Corporation, Bethesda, MD (US)

(21) Appl. No.: 15/003,577

(22) Filed: Jan. 21, 2016

(51) Int. Cl. G01N 21/63; G01B 11/16; G01R 33/032; G01N 21/66; G01R 33/12

(52) U.S. Cl. CPC G01N 21/63; G01N 21/66; G01R 33/12; G01R 33/032; G01B 11/16

(57) ABSTRACT

A system measures the quantum energy levels of a diamond nitrogen vacancy (DNV) material to provide information regarding the quality of the material. The measurements may provide information regarding the degree of strain in the crystal lattice of the material, the concentration of crystal defect in the material, the concentration of nitrogen vacancy (NV) centers in the material, or the concentration of impurities in the material. The system may be employed to perform quality control checks on the properties of the DNV material quickly and non-destructively.

### BACKGROUND

The present disclosure generally relates to a method and system for determining the quality of diamond nitrogen vacancy (DNV) materials. The quality of DNV materials impacts the suitability of the material for various applications, such as magnetic field sensors. Thus, a method of quickly and non-destructively determining the quality of DNV materials is desired.

### SUMMARY

Some embodiments relate to a system that may comprise: a nitrogen vacancy (NV) diamond material comprising a plurality of NV centers; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a degree of strain in a crystal lattice of the NV diamond material based on a received light detection signal from the optical detector. The controller may be further configured to determine a concentration of crystal lattice defects in the NV diamond material based on the received light detection signal from the optical detector. The controller may be further configured to control the optical excitation source to provide continuous wave (CW) excitation to the NV diamond material, and control the RF excitation source to provide CW RF excitation to the NV diamond material. The controller may be further configured to determine the degree of strain in the crystal lattice of the NV diamond material by resolving the location of lorentzian peaks in the received light detection signal from the optical detector.

Other embodiments relate to a system that may comprise: a nitrogen vacancy (NV) diamond material comprising a plurality of NV centers; a magnetic field source; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a concentration of the NV centers in the NV diamond material based on a received light detection signal from the optical detector. The controller may be further configured to determine the concentration of the NV centers in the NV diamond material by resolving hyperfines in the received light detection signal from the optical detector. The controller may be further configured to determine the concentration of impurities in the NV diamond material. The impurities may include at least one of 15N or 13C. The controller may be configured to determine the concentration of impurities in the NV by determining the location of hyperfines in the received light detection signal from the optical detector.

Other embodiments relate to a system that may comprise: a nitrogen vacancy (NV) diamond material comprising a plurality of NV centers; a magnetic field generator configured to produce a magnetic field; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to control the magnetic field generator to apply or not apply a magnetic field at the NV diamond material, determine a degree of strain in a crystal lattice of the NV diamond material based on a received light detection signal from the optical detector when the magnetic field is not applied to the NV diamond material, and determine a concentration of the NV centers in the NV diamond material based on a received light detection signal from the optical detector when the magnetic field is applied to the NV diamond material. The controller may be configured to determine the concentration of the NV centers in the NV diamond material by resolving hyperfines in the received light detection signal from the optical detector. The controller may be further configured to determine the concentration of impurities in the NV diamond material. The impurities may include at least one of 15N or 13C. The controller may be configured to determine the concentration of impurities in the NV by determining the location of hyperfines in the received light detection signal from the optical detector. The controller may be further configured to determine a concentration of crystal lattice defects in the NV diamond material based on the received light detection signal from the optical detector when the magnetic field is not applied to the NV diamond material. The controller may be further configured to control the optical excitation source to provide continuous wave (CW) excitation to the NV diamond material, and control the RF excitation source to provide CW RF excitation to the NV diamond material. The controller may be further configured to determine the degree of strain in the crystal lattice of the NV diamond material by resolving the location of lorentzian peaks in the received light detection signal from the optical detector when the magnetic field is not applied to the NV diamond material.

Other embodiments relate to a system that may comprise: a nitrogen vacancy (NV) diamond material comprising a plurality of NV centers; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a degree of strain in a crystal lattice of the NV diamond material based on a received light detection signal from the optical detector when the magnetic field, and determine whether the degree of strain in the crystal lattice of the NV diamond exceeds a threshold value. The threshold value may be a previously determined degree of strain stored in a memory of the controller, such as a maximum acceptable degree of strain. The controller may be further configured to determine a concentration of crystal lattice defects in the NV diamond material based on the received light detection signal from the optical detector, and determine whether the concentration of crystal lattice defects in the NV diamond material exceeds a threshold value.

Other embodiments relate to a system that may comprise: a nitrogen vacancy (NV) diamond material comprising a plurality of NV centers; a magnetic field source configured to apply a magnetic field to the NV diamond material; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a concentration of the NV centers in the NV diamond material based on a received light detection signal from the optical detector, and determine whether the concentration of NV centers in the NV diamond material exceeds a threshold value. The threshold value may be a previously determined concentration of NV centers stored in a memory of the controller.

Other embodiments relate to a system that may comprise: a nitrogen vacancy (NV) diamond material comprising a plurality of NV centers; a magnetic field source configured to apply a magnetic field to the NV diamond material; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a concentration of impurities in the NV diamond material based on a received light detection signal from the optical detector, and determine whether the concentration of impurities in the NV diamond material exceeds a threshold value. The threshold value may be a previously determined concentration of impurities stored in a memory of the controller.

Other embodiments relate to a system that may comprise: a nitrogen vacancy (NV) diamond material comprising a plurality of NV centers; a radio frequency (RF) excitation source configured to provide RF excitation to the NV diamond material; an optical excitation source configured to provide optical excitation to the NV diamond material; an optical detector configured to receive an optical signal emitted by the NV diamond material; and a controller. The controller may be configured to determine a concentration of crystal lattice defects in a crystal lattice of the NV diamond material based on a received light detection signal from the optical detector, and determine whether the concentration of crystal lattice defects in the crystal lattice of the NV diamond exceeds a threshold value. The threshold value may be a previously determined concentration of crystal lattice defects stored in a memory of the controller.

### BRIEF DESCRIPTION OF THE DRAWINGS

FIG. 1 illustrates one orientation of an NV center in a diamond lattice.

FIG. 2 is an energy level diagram illustrates energy levels of spin states for an NV center.

FIG. 3 is a schematic illustrating an NV center magnetic sensor system.

FIG. 4 is a graph illustrating fluorescence as a function of applied RF frequency of an NV center along a given direction for a zero magnetic field and a non-zero magnetic field.

FIG. 5 is a graph illustrating fluorescence as a function of applied RF frequency for four different NV center orientations for a non-zero magnetic field.

FIG. 6 is a depiction of the energy levels of an NV center which contribute to the Hamiltonian thereof.

FIG. 7 is a graph illustrating fluorescence as a function of applied RF frequency of an NV center for a zero external magnetic bias field.

FIG. 8 is a graph illustrating fluorescence as a function of applied RF frequency of a high quality NV center sample for an applied external magnetic bias field.

FIG. 9 is a graph illustrating fluorescence as a function of applied RF frequency of a low quality NV center sample for an applied external magnetic bias field.

FIG. 10 is a schematic illustrating a NV center magnetic sensor system.

### DETAILED DESCRIPTION

Measuring the quantum energy levels of a diamond nitrogen vacancy (DNV) material may provide information regarding the quality of the material, such as the suitability of the DNV material for use in a magnetic field sensor. The impurity content, lattice strain, and nitrogen vacancy (NV) concentration of the DNV material impact the quantum energy levels of the DNV material. Thus, measuring the quantum energy levels of the DNV material provides information regarding the impurity content, lattice strain, and NV content of the DNV material.

NV Center, its Electronic Structure, and Optical and RF Interaction

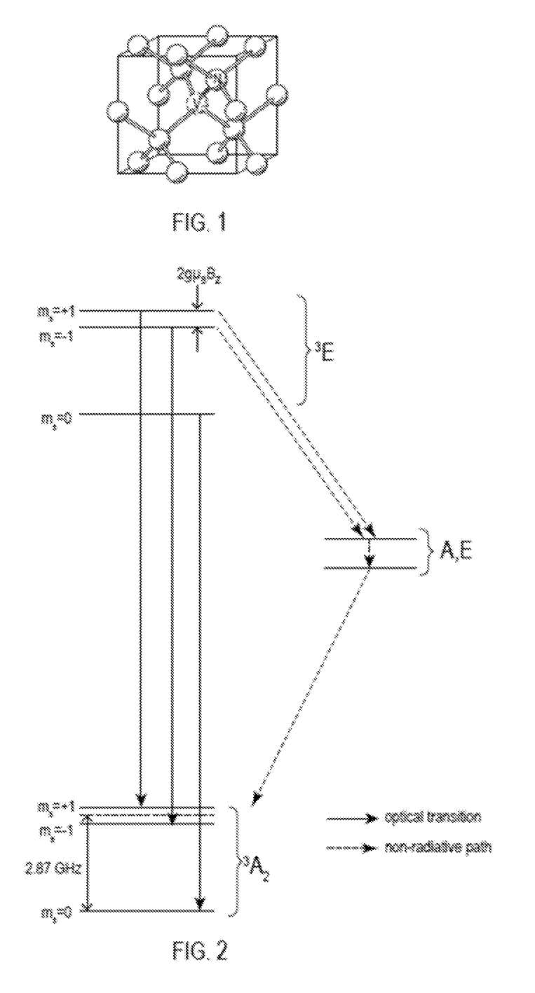

The nitrogen vacancy (NV) center in diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. Conventionally, the neutral charge state uses the nomenclature NV⁰, while the negative charge state uses the nomenclature NV, which is adopted in this description.

The NV center has a number of electrons including three unpaired electrons, one from each of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}Bz, where g is the g-factor, μ_{B} is the Bohr magneton, and Bz is the component of the external magnetic field along the NV axis. This relationship is correct for a first order and inclusion of higher order corrections is a straight forward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states which have the same spin. For a direct transition between the excited triplet ³E and the ground state ³A₂, a photon of red light is emitted with a photon energy corresponding to the energy difference between the energy levels of the transitions.

There is, however, an alternate non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than that from the mₛ=0 spin state of the excited triplet ³E to the intermediate energy levels. The transition from the singlet states A, E to the ground state triplet ³A₂ predominantly decays to the mₛ=0 spin state over the mₛ=±1 spin states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

NV Center Sensor System

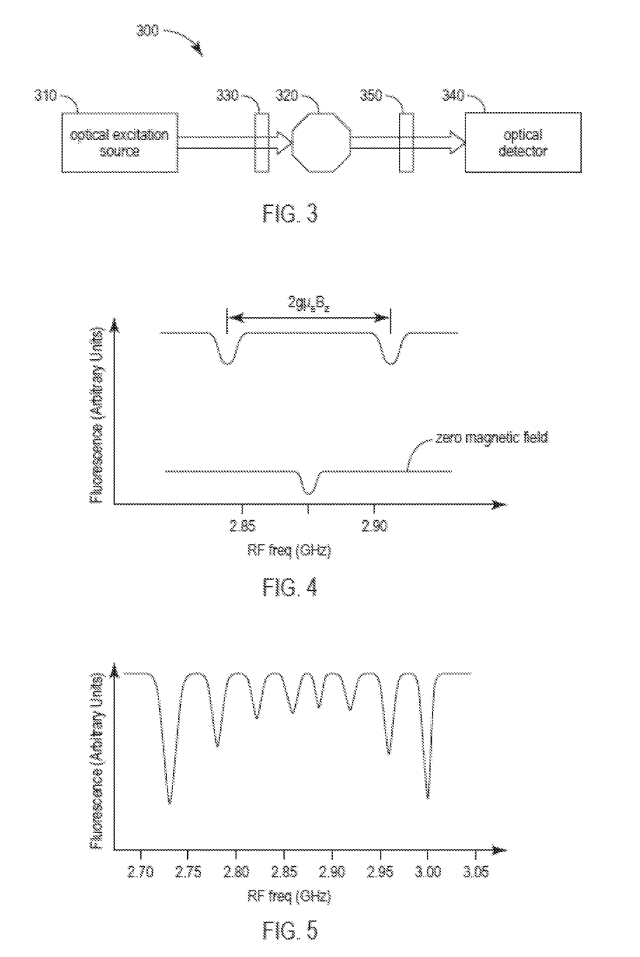

FIG. 3 is a schematic illustrating a NV center sensor system 300 which uses fluorescence intensity to distinguish the mₛ=±1 states. The sensor system may include components similar to or the same as the components of a magnetic field sensor system that includes DNV and determines the magnetic field based on the energy difference between the mₛ=+1 state and the mₛ=−1 state. The system 300 includes an optical excitation source 310, which directs optical excitation to an NV diamond material 320 with NV centers. The system 300 further includes an RF excitation source 330 which provides RF radiation to the NV diamond material 320. Light from the NV diamond may be directed through an optical filter 350 to an optical detector 340.

The RF excitation source 330 may be a microwave coil, for example. The RF excitation source 330 when emitting RF radiation with a photon energy resonant with the transition energy between ground mₛ=0 spin state and the mₛ=+1 spin state excites a transition between those spin states. For such a resonance, the spin state cycles between ground mₛ=0 spin state and the mₛ=+1 spin state, reducing the population in the mₛ=0 spin state and reducing the overall fluorescence at resonance. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state. At resonance between the mₛ=0 spin state and the mₛ=−1 spin state, or between the mₛ=0 spin state and the mₛ=+1 spin state, there is a decrease in the fluorescence intensity.

The optical excitation source 310 may be a laser or a light emitting diode, for example, which emits light in the green, for example. The optical excitation source 310 induces fluorescence in the red, which corresponds to an electronic transition from the excited state to the ground state. Light from the NV diamond material 320 is directed through the optical filter 350 to filter out light in the excitation band (in the green fluorescence band for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range which includes the zero splitting (when the mₛ=±1 spin states have the same energy) photon energy of 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples, of pulsed excitation schemes include Ramsey pulse sequence, and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined.

Characterization of DNV Material

The characterization of DNV materials may be achieved by measuring a number of parameters associated with the fluorescence behavior described above. For example, DNV metrology may be carried out through the measurement of a number of parameters associated with the Zero-Field-Splitting (ZFS) of the DNV dipolar coupling and the Hyperfine coupling of the DNV material. The measurement of these parameters allows assessment of the impurities in the diamond. Examples of the impurities are lattice dislocations, broken bonds, and other elements beyond 14-Nitrogen. Measurement of these parameters further affords insight as to the concentration of DNV centers. Impurities and excess DNV concentration directly impact the hyperfine resolution. Lattice dislocations and crystal strain can affect the ZFS level by introducing an asymmetry that breaks the degeneracy of the state. The assessment pursued by the measurements maybe conducted in a reasonably short period of time, and provides sufficient depth of information such that the quality of the DNV material may be confirmed. Such a quality assurance (QA) assessment is desirable when evaluating and comparing various DNV suppliers or when confirming the properties of DNV materials.

The characterization of a DNV sample includes measurements of the quantum nature of the sample. The ZFS parameters are derived from the Hamiltonian (Energy Equation) to a specific precision for the DNV system. The Hamiltonian can be expressed as:

H=H_{Zeeman}+H_{Dipolar}+H_{Hyperfine}+H_{Quadrapole}_{_{nuclear}}

where:

H_{Zeeman}=−μ_{B}S̅^{T}g̅B̅

H_{Dipolar}=−hS̅^{T}D̅S̅

H_{Hyperfine}=−hS̅^{T}A̅1

H_{Quadrapole}_{_}_{Nuclear}=−h1+Q̅1

The Zeeman term describes the interaction of the spin centers with an external magnetic field. Measurements of the terms D̅, A̅, and Q̅ provide significant insight into the repeatability and quality of the DNV manufacturing process.

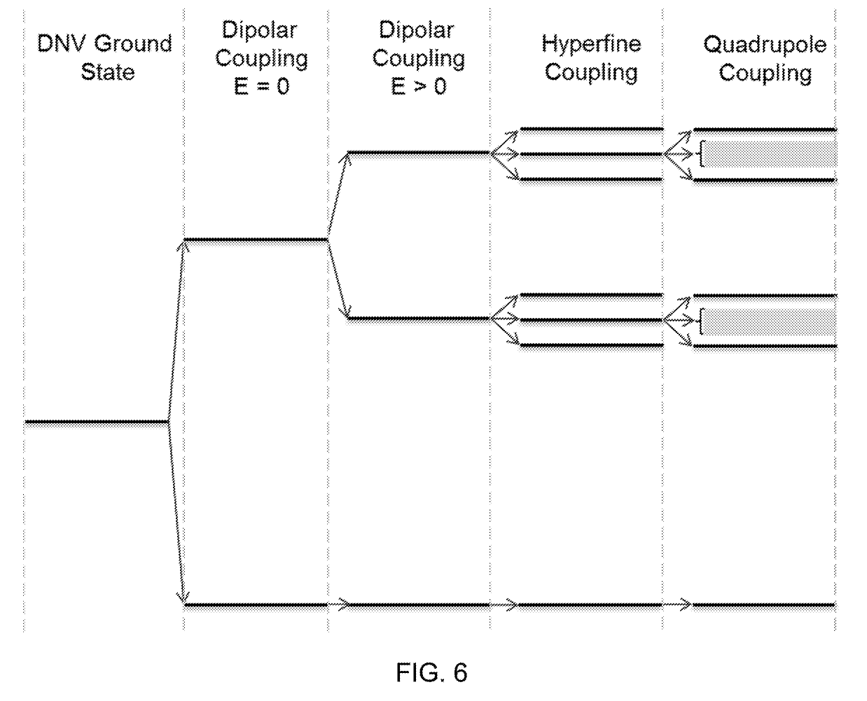

A schematic depiction of the energy levels of the DNV Hamiltonian is shown in FIG. 6. In the diagram of FIG. 6, the DNV ground state level and various splitting of the energy levels due to different couplings such as dipolar couplings (with E=0 and E>0), hyperfine coupling, and quadrupole coupling are shown.

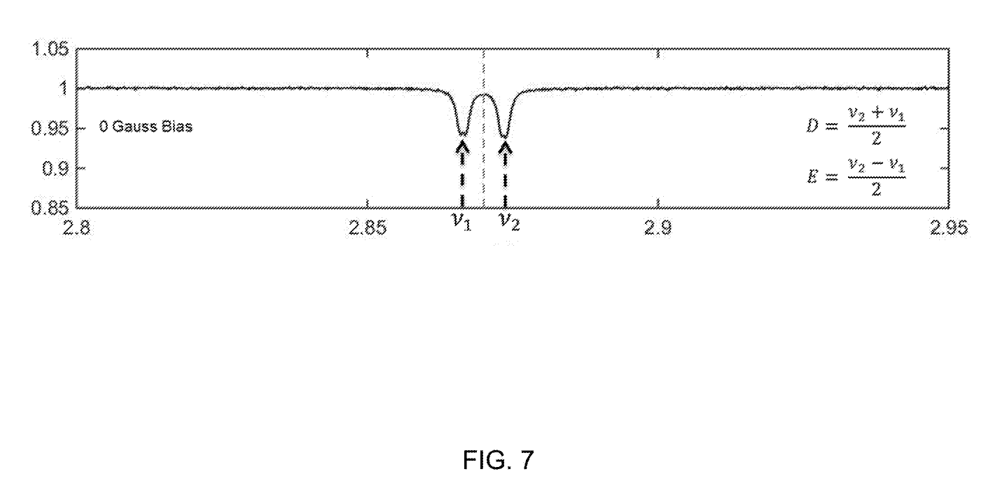

The terms D̅, A̅, and Q̅ provide insight into the repeatability and quality of the DNV manufacturing process because the terms D̅, A̅, and Q̅ from the Hamiltonian equation are measurable quantities that determine the energy levels of the DNV system. In the DNV reference frame aligned to the NV center, the D̅ tensor may be expressed as:

$${D}^{\overline{\_}} = [ \begin{matrix}\text{?} & 0 & 0 \\ 0 & \text{?} & 0 \\ 0 & 0 & \text{?}\end{matrix} ] , \\ \text{?} \text{indicates text missing or illegible when filed}$$

where the parameter D is the ZFS amount. D typically has a value of ˜2.870 GHz. The parameter E is an additional symmetry breaking term, and may be on the order of a few MHz. Combining these two parameters provides information regarding the degree of strain in the diamond lattice. FIG. 7 is a diagram illustrating an example of a DNV fluorescence signal as described above without an applied bias field (0 gauss bias). The parameters E and D are derived from the measured frequencies ν₁ and ν₂ of the DNV optical signal of FIG. 7 according to following equations:

$$D = \frac{{v}_{2} + {v}_{1}}{2} , \\ E = \frac{{v}_{2} - {v}_{1}}{2} .$$

The measured frequencies ν₁ and ν₂ of the DNV signal may be considered to be the location of lorentzian peaks in the DNV optical signal, as shown in FIG. 7.

To produce a fluorescence signal of the DNV material, a continuous wave (CW) laser pumping and a continuous-wave (CW) radio-frequency (RF) can be employed for excitation of the DNV sample, in the absence of an applied bias magnetic field. The RF signal can be swept from ˜2.8 to 2.95 GHz to observe the fluorescence signal shown in FIG. 7.

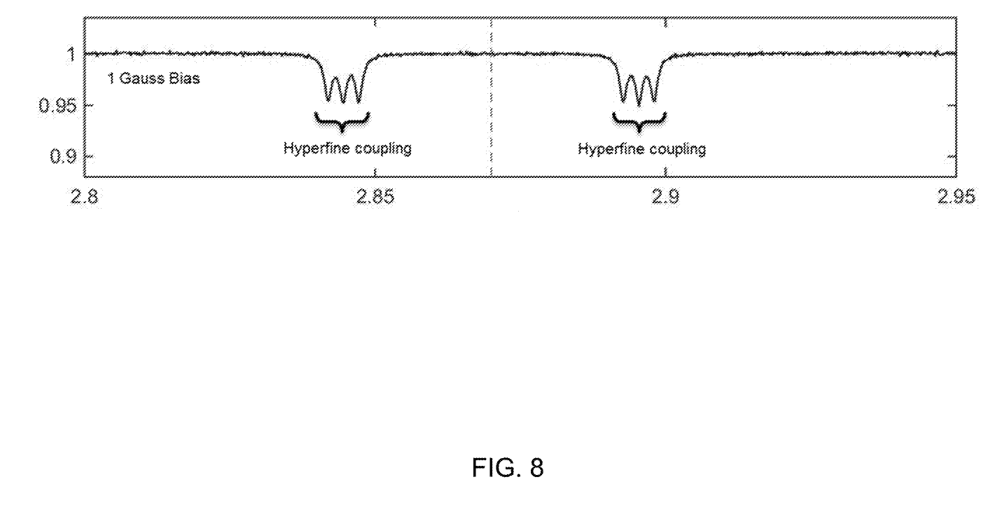

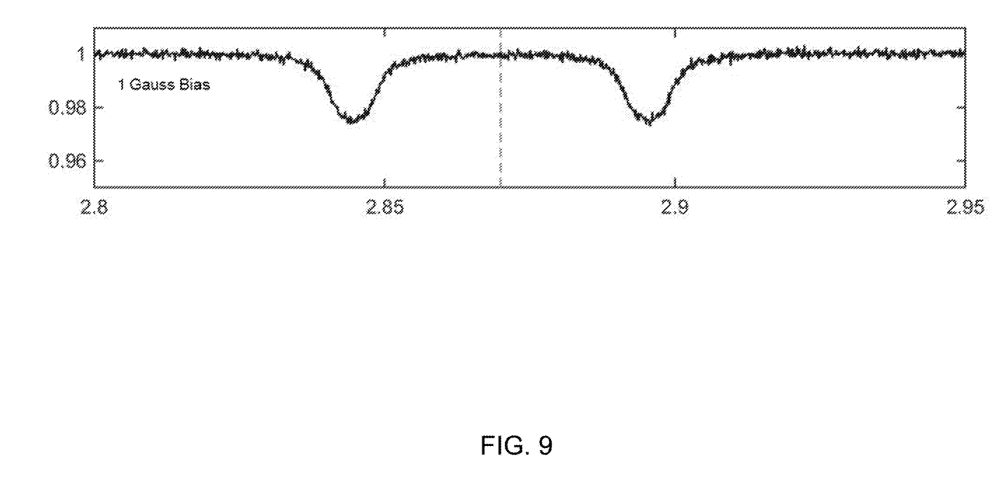

The A̅ tensor of the Hamiltonian is associated with the hyperfine splitting shown in FIG. 8. Identifying and measuring hyperfine values provides information regarding the purity of the DNV sample and the concentration of N/NV. FIGS. 8 and 9 are diagrams illustrating DNV florescence signals for a high quality DNV sample and a low quality DNV sample, respectively, under a 1 Gauss magnetic bias field. The locations of the hyperfine levels may indicate the presence of isotopes of ¹⁵N, ¹⁴N, and ¹³C in the DNV sample. The natural isotope ¹⁴N has known levels of approximately +2.5 MHz, 0 MHz, and −2.5 MHz relative to the dipolar energy levels, as shown in FIG. 8. The ability to resolve hyperfine levels at room temperature, as seen in FIG. 8, indicates a high purity of the DNV sample. A high purity DNV sample may allow hyperfine levels to be resolved without cooling the DNV sample to cryogenic temperatures. Samples with low purity or high N/NV concentration effectively blur the hyperfine peaks such that they are unresolvable, as shown in FIG. 9. The inability to resolve hyperfine levels is an indication of a low purity or high defect DNV sample.

To determine the existence of the hyperfine resonance, a small bias magnetic field is applied to the DNV sample along with continuous wave (CW) laser pumping and a CW RF excitation. In some implementations, the RF power may be beneficially adjusted to the lowest setting possible while still obtaining measurable resonances. The RF signal can be swept from ˜2.8 to 2.95 GHz to observe the fluorescence signal shown in FIG. 8, which utilized a 1 gauss bias magnetic field. The bias magnetic field applied to identify and measure the hyperfine splitting may be any appropriate bias field, such as at least about 1 gauss, or about 30 gauss.

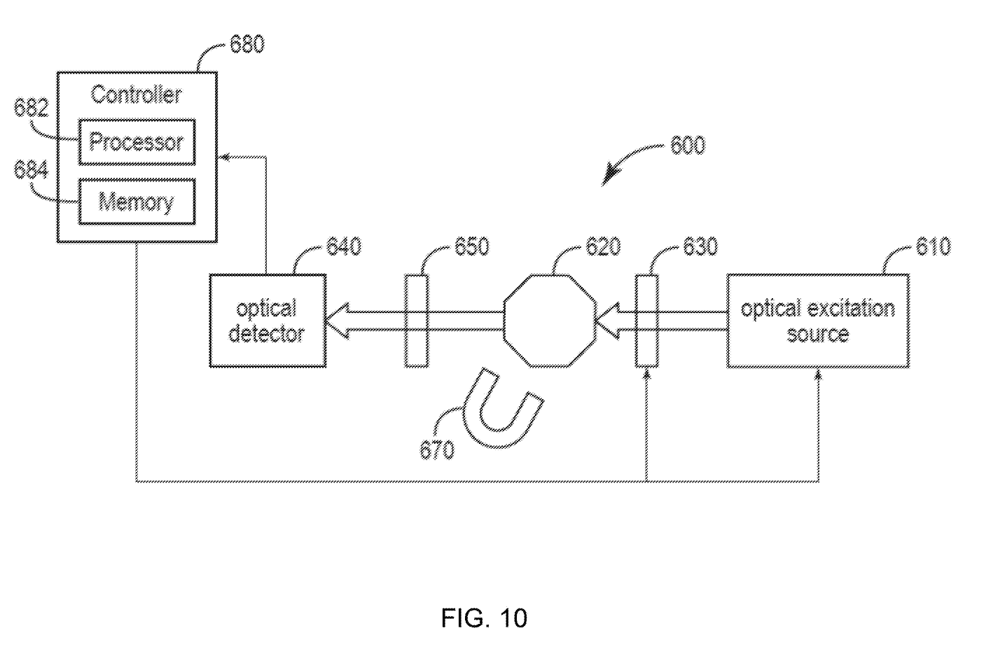

FIG. 10 is a schematic of an NV center sensor 600, according to some embodiments. The sensor 600 includes an optical excitation source 610, which directs optical excitation to an NV diamond material 620 with NV centers. An RF excitation source 630 provides RF radiation to the NV diamond material 620. The NV center sensor 600 may include a bias magnetic field source 670, such as a permanent magnet or electromagnet, applying a bias magnetic field to the NV diamond material 620. Light from the NV diamond material 620 may be directed through an optical filter 650 and an electromagnetic interference (EMI) filter 660, which suppresses conducted interference, to an optical detector 640. The sensor 600 further includes a controller 680 arranged to receive a light detection signal from the optical detector 640 and to control the optical excitation source 610 and the RF excitation source 630.

The RF excitation source 630 may be a microwave coil, for example. The RF excitation source 630 is controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green band, for example. The optical excitation source 610 induces fluorescence of the NV diamond material in the red band, which corresponds to an electronic transition from the excited state to the ground state. Light from the NV diamond material 620 is directed through the optical filter 650 to filter out light in the excitation band (in the green for example), and to pass light in the red fluorescence band, which in turn is detected by the optical detector 640. The EMI filter 660 is arranged between the optical filter 650 and the optical detector 640 and suppresses conducted interference. The optical excitation light source 610, in addition to exciting fluorescence in the NV diamond material 620, also serves to reset the population of the mₛ=0 spin state of the ground state ³A₂ to a maximum polarization, or other desired polarization.

The controller 680 is arranged to receive a light detection signal from the optical detector 640 and to control the optical excitation source 610 and the RF excitation source 630. The controller may include a processor 682 and a memory 684, in order to control the operation of the optical excitation source 610 and the RF excitation source 630. The memory 684, which may include a nontransitory computer readable medium, may store instructions to allow the operation of the optical excitation source 610 and the RF excitation source 630 to be controlled.

According to some embodiments of operation, the controller 680 controls the operation such that the optical excitation source 610 continuously pumps the NV centers of the NV diamond material 620. The RF excitation source 630 is controlled to continuously sweep across a frequency range which includes the zero splitting (when the mₛ=±1 spin states have the same energy) photon energy of 2.87 GHz. When the photon energy of the RF radiation emitted by the RF excitation source 630 is the difference in energies of the mₛ=0 spin state and the mₛ=−1 or mₛ=+1 spin state, the overall fluorescence intensity is reduced at resonance, as discussed above with respect to FIG. 3. In this case, there is a decrease in the fluorescence intensity when the RF energy resonates with an energy difference of the mₛ=0 spin state and the mₛ=−1 or mₛ=+1 spin states.

According to some embodiments, the NV center sensor 600 may also function as a magnetic field sensor. As noted above, the diamond material 620 will have NV centers aligned along directions of four different orientation classes, and the component Bz along each of the different orientations may be determined based on the difference in energy between the mₛ=−1 and the mₛ=+1 spin states for the respective orientation classes. In certain cases, however, it may be difficult to determine which energy splitting corresponds to which orientation class, due to overlap of the energies, etc. The bias magnetic field source 670 provides a magnetic field, which is preferably uniform on the NV diamond material 620, to separate the energies for the different orientation classes, so that they may be more easily identified. In this way the component of the magnetic field Bz along the NV axis may be determined by the difference in energies between the mₛ=−1 and the mₛ=+1 spin states.

DNV Material Assessment Systems

The assessment of the DNV material may take place in a dedicated test system prior to incorporation of the DNV material in a sensor system or after the DNV material has been incorporated in a sensor system, such as a magnetic field sensor. The use of a dedicated test system allows the DNV material to be evaluated after production or upon receipt from a supplier. In this manner it can be assured that the DNV material exhibits the desired properties before incorporation in to a device. Assessing the DNV material after incorporation in a sensor system allows the condition of the DNV material to be monitored throughout the lifetime of the sensor system. This arrangement allows the DNV material to be monitored and a user alerted if the DNV material is damaged or degrades to an extent that the accuracy or operation of the sensor system would be negatively impacted.

A dedicated test system for assessment of the DNV material may include the features of the NV sensor system depicted in FIG. 6 and described above. As described above, the zero field splitting (ZFS) amount of the DNV material is measured in the absence of an external magnetic field. For the measurement of ZFS amount, the bias magnetic field source 670 may be omitted from the sensor system. Alternatively, a switchable bias magnetic field source 670, such as an electromagnet, may be employed in the off state when measuring the ZFS amount. Magnetic shielding may be included in the sensor system to reduce or eliminate the magnetic field acting on the DNV material during the measurement of the ZFS amount.

The test system may include a controller of the type depicted in FIG. 6. The controller may be programmed to control the optical excitation source and the RF excitation source to produce a luminescence signal at the optical detector. The controller is also programmed to determine the ZFS amount, D and E from the luminescence signal received by the optical detector in the manner described above. During the measurement of the ZFS amount, D and E, a magnetic bias field is not applied to the DNV material.

The test system may include an automated system for disposing the DNV material in the test system. The automated system may include any component capable of disposing the DNV material in the test system. Alternatively, the test system may be configured such that a user can place the DNV sample in the test system.

As described above, the ZFS amount, D and E provide insight into the degree of strain in the crystal lattice of the DNV material. The controller may be programmed to determine the degree of strain in the crystal lattice of the DNV material based on the measured ZFS amount, D and E. Determining the degree of strain in the crystal lattice may include comparing the measured ZFS amount, D and E to pre-determined threshold values stored in the memory of the controller. In the case that the measured ZFS amount, D and E fall within the range defined by the threshold values, the degree of strain in the crystal lattice of the DNV material is determined to be acceptable.

The ZFS amount, D and E also provide insight into the concentration of crystal lattice defects present in the DNV material. The controller may be programmed to determine the concentration of crystal lattice defects in the crystal lattice of the DNV material based on the measured ZFS amount, D and E. Determining the concentration of crystal lattice defects in the crystal lattice may include comparing the measured ZFS amount, D and E to pre-determined threshold values stored in the memory of the controller. In the case that the measured ZFS amount, D and E fall within the range defined by the threshold values, the concentration of crystal lattice defects in the crystal lattice of the DNV material is determined to be acceptable. The threshold values for ZFS amount, D and E may be any appropriate value that is associated with a DNV material that exhibits the desired properties. For example, a threshold value for D may be between 2.5 and 5.5 MHz.

The controller may be programmed to determine whether hyperfines are resolvable in a luminescence signal received at the optical detector when a magnetic bias is applied to the DNV material. The controller may be programmed to control the optical excitation source and the RF excitation source to produce the luminescence signal at the optical detector. Additionally, the controller may be programmed to control a magnetic bias generator, such that a magnetic bias field is applied to the DNV material. The magnetic bias field applied to the DNV material may be a small magnetic bias field, such as ˜30 gauss. The test system utilized to determine whether hyperfines are resolvable may be the same test system employed to measure the ZFS amount, D and E. Alternatively, the test system utilized to determine whether hyperfines are resolvable may be a different test system than the test system employed to measure the ZFS amount, D and E.

As described above, the ability to resolve hyperfines in the luminescence signal received at the optical detector provides insight as the concentration of NV centers and impurities in the DNV material. A hyperfine may be considered to be resolvable when the full width half maximum value for the hyperfine is measurable from the luminescence signal received at the optical detector. The ability to resolve hyperfines indicates that the concentration of NV centers and impurities in the DNV material is in an acceptable range. Impurities may be considered the inclusion of components in the DNV material that deviate from the intent of manufacture.

In some cases, the presence of hyperfines in addition to those associated with the natural isotope ¹⁴N shown in FIG. 8 may indicate that additional impurity species are present in the DNV material. For example, hyperfines at other locations in the luminescence signal may indicate that isotopes of ¹⁵N, and/or ¹³C are present in the DNV sample. In general, the ability to resolve hyperfines in the luminescence signal indicates that the DNV material is of sufficient purity. According to some embodiments, where a high purity DNV material including ¹⁴N and ¹²C is desired ¹⁵N and ¹³C isotopes are considered impurities. According to some other embodiments, where a high purity DNV material including ¹⁵N and ¹²C is desired ¹⁴N and ¹³C isotopes are considered impurities.

The assessment of the DNV material may be carried out in a sensor system. For example, the controller of a DNV magnetic field sensor may be programmed to measure the ZFS amount, D and E and determine whether hyperfines can be resolved as described above. The result of the measurement of ZFS amount, D and E may be compared to a threshold value stored in a memory of the controller. In the event that the measured values fall outside of the desired threshold value ranges, an error message may be communicated to a user of the sensor system. Similarly, if hyperfines are not capable of being resolved, an error message may be communicated to a user of the sensor system. The error message may be communicated to a user by any appropriate means, such as a display, error light, or wireless communication. The ability to resolve hyperfines may be considered to indicate that a concentration of NV centers in the DNV material and/or a concentration of impurities in the DNV material are within a desired range. The ability to resolve hyperfines may indicate a concentration on the order of at least parts per million.

The assessment of the DNV material in the sensor system may be carried out periodically. For example, the assessment may be carried out hourly or daily while the sensor is in use. Alternatively, the assessment of the DNV material may be carried out when the sensor is moved or has been subjected to an event that may have damaged the DNV material. In this manner, the assessment of the DNV material may be carried out throughout the lifetime of the sensor system. This ensures that the DNV material produces acceptable performance over the lifetime of the sensor system. The performance of the sensor system may be negatively impacted if the DNV material exhibits an increased strain, concentration of crystal lattice defects, concentration of impurities, or change in NV center concentration. The assessment of the DNV material throughout the lifetime of the sensor system warns a user of such an occurrence.

The result of the assessment of the DNV material may be stored in a memory of the controller. The stored assessment results may then be utilized to monitor a trend in the properties of the DNV material over time. This information may provide insight into potential future problems with the DNV material in the sensor system, or provide a warning regarding the degradation of the DNV material. For example, an increase in the degree of strain in the crystal lattice over time may indicate that a stress induced fracture of the DNV material is imminent.

The DNV assessment systems and methods described herein are capable of quickly and non-destructively performing quality control checks on DNV materials. The systems are capable of sufficient throughput to operate in line with a DNV sensor manufacturing line, and provide sufficient information regarding the properties of the DNV material to establish that the DNV material is acceptable for use.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A system comprising,
a nitrogen vacancy (NV) diamond material comprising a plurality of NV centers;
a magnetic field generator configured to produce a magnetic field;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
control the magnetic field generator to apply or not apply a magnetic field at the NV diamond material,
determine a degree of strain in a crystal lattice of the NV diamond material based on a received light detection signal from the optical detector when the magnetic field is not applied to the NV diamond material, and
determine a concentration of the NV centers in the NV diamond material based on a received light detection signal from the optical detector when the magnetic field is applied to the NV diamond material.

2. The system of claim 1, wherein the controller is configured to determine the concentration of the NV centers in the NV diamond material by resolving hyperfines in the received light detection signal from the optical detector.

3. The system of claim 1, wherein the controller is further configured to determine the concentration of impurities in the NV diamond material.

4. The system of claim 3, wherein the impurities include at least one of ¹⁵N or ¹³C.

5. The system of claim 3, wherein the controller is configured to determine the concentration of impurities in the NV by determining the location of hyperfines in the received light detection signal from the optical detector.

6. The system of claim 1, wherein the controller is further configured to determine a concentration of crystal lattice defects in the NV diamond material based on the received light detection signal from the optical detector when the magnetic field is not applied to the NV diamond material.

7. The system of claim 1, wherein the controller is further configured to:
control the optical excitation source to provide continuous wave (CW) excitation to the NV diamond material, and
control the RF excitation source to provide CW RF excitation to the NV diamond material.

8. The system of claim 1, wherein the controller is further configured to determine the degree of strain in the crystal lattice of the NV diamond material by resolving the location of lorentzian peaks in the received light detection signal from the optical detector when the magnetic field is not applied to the NV diamond material.

9. A system comprising:
a nitrogen vacancy (NV) diamond material comprising a plurality of NV centers;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a degree of strain in a crystal lattice of the NV diamond material based on a received light detection signal from the optical detector when the magnetic field, and
determine whether the degree of strain in the crystal lattice of the NV diamond exceeds a threshold value.

10. The system of claim 9, wherein the threshold value is a previously determined degree of strain stored in a memory of the controller.

11. The system of claim 9, wherein the threshold value is a maximum acceptable degree of strain.

12. The system of claim 9, wherein the controller is further configured to:
determine a concentration of crystal lattice defects in the NV diamond material based on the received light detection signal from the optical detector, and
determine whether the concentration of crystal lattice defects in the NV diamond material exceeds a threshold value.

13. A system, comprising:
a nitrogen vacancy (NV) diamond material comprising a plurality of NV centers;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a degree of strain in a crystal lattice of the NV diamond material by resolving the location of lorentzian peaks in a received light detection signal from the optical detector.

14. The system of claim 1, wherein the controller is further configured to determine a concentration of crystal lattice defects in the NV diamond material based on the received light detection signal from the optical detector.

15. The system of claim 1, wherein the controller is further configured to:
control the optical excitation source to provide continuous wave (CW) excitation to the NV diamond material, and
control the RF excitation source to provide CW RF excitation to the NV diamond material.

16. A system comprising,
a nitrogen vacancy (NV) diamond material comprising a plurality of NV centers;
a magnetic field source;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a concentration of the NV centers in the NV diamond material based on a received light detection signal from the optical detector.

17. The system of claim 16, wherein the controller is configured to determine the concentration of the NV centers in the NV diamond material by resolving hyperfines in the received light detection signal from the optical detector.

18. The system of claim 16, wherein the controller is further configured to determine the concentration of impurities in the NV diamond material.

19. The system of claim 18, wherein the impurities include at least one of ¹⁵N or ¹³C.

20. The system of claim 18, wherein the controller is configured to determine the concentration of impurities in the NV by determining the location of hyperfines in the received light detection signal from the optical detector.

21. A system comprising,
a nitrogen vacancy (NV) diamond material comprising a plurality of NV centers;
a magnetic field source configured to apply a magnetic field to the NV diamond material;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a concentration of the NV centers in the NV diamond material based on a received light detection signal from the optical detector, and
determine whether the concentration of NV centers in the NV diamond material exceeds a threshold value.

22. The system of claim 21, wherein the threshold value is a previously determined concentration of NV centers stored in a memory of the controller.

23. A system comprising,
a nitrogen vacancy (NV) diamond material comprising a plurality of NV centers;
a magnetic field source configured to apply a magnetic field to the NV diamond material;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a concentration of impurities in the NV diamond material based on a received light detection signal from the optical detector, and
determine whether the concentration of impurities in the NV diamond material exceeds a threshold value.

24. The system of claim 23, wherein the threshold value is a previously determined concentration of impurities stored in a memory of the controller.

25. A system comprising:
a nitrogen vacancy (NV) diamond material comprising a plurality of NV centers;
a radio frequency (RF) excitation source configured to provide RF excitation to the NV diamond material;
an optical excitation source configured to provide optical excitation to the NV diamond material;
an optical detector configured to receive an optical signal emitted by the NV diamond material; and
a controller configured to:
determine a concentration of crystal lattice defects in a crystal lattice of the NV diamond material based on a received light detection signal from the optical detector, and
determine whether the concentration of crystal lattice defects in the crystal lattice of the NV diamond exceeds a threshold value.

26. The system of claim 25, wherein the threshold value is a previously determined concentration of crystal lattice defects stored in a memory of the controller.
